(19) United States
(12) Patent Application Publication
(10) Pub. No.: US 2014/0367850 A1
(43) Pub. Date: Dec. 18, 2014

(54) STACKED PACKAGE AND METHOD OF FABRICATING THE SAME

(71) Applicant: Siliconware Precision Industries Co., Ltd., Taichung (TW)

(72) Inventor: Lung-Yuan Wang, Taichung Hsien (TW)

(73) Assignee: Siliconware Precision Industries Co., Ltd., Taichung (TW)

(21) Appl. No.: 14/077,771

(22) Filed: Nov. 12, 2013

(30) Foreign Application Priority Data
Jun. 18, 2013 (TW) 102121483

(51) Int. Cl. H01L 23/00

(52) U.S. Cl. CPC H01L 24/17; H01L 24/81; H01L 24/25; H01L 24/82
USPC 257/737; 438/107

(57) ABSTRACT

A stacked package and a method of fabricating the same are provided. The stacked package includes: a first package, having a first encapsulant, a first electrical connection structure formed on one surface of the first encapsulant, a plurality of first conductive pillars formed in the first encapsulant, and a first semiconductor chip disposed in the first encapsulant are electrically connected to the first electrical connection structure; and a second package stacked on the first package, wherein the second package has a second encapsulant, a second electrical connection structure formed on the second encapsulant, a second semiconductor, a chip disposed in the second encapsulant and electrically connected to the second electrical connection structure, and a plurality of second conductive pillars formed in the second encapsulant and electrically connected to the first electrical conduction pillars. The stacked package can provide a great number of inputs/outputs for electronic applications.

### BACKGROUND OF THE INVENTION

1. Field of the Invention

This invention relates to semiconductor wafers, and, more particularly, to a stacked package with fine pitch input/output feature and a method of fabricating a stacked package.

2. Description of Related Art

With the advance of modern science and technology, the current trends in the electronic products have been developed toward miniaturization, multi-function, high performance, and high-speed operation characteristics, therefore nowadays the semiconductor manufacturers follow this trend to develop the semiconductor package with the features of small size, high performance, high functionality, and high speed in order to meet the requirements of the electronic products.

FIG. 1 is a sectional view illustrating a stacked package according to the prior art. As shown in FIG. 1, all electrode pads (not shown) of a semiconductor chip 11 of a package 1 on the stacked package are required to be connected to electrical connection pads 121 surrounding an upper package substrate 12. First bumps 13 on the bottom surface of the upper package substrate 12 are electrically bonded to second bumps 22 surrounding a lower package substrate 21 of the lower package 2. The stacked package is electrically bonded to an outside region via third bumps 23 on the bottom surface of the lower package substrate 21.

Since all of the electrode pads of the semiconductor chip 11 of the upper package 1 are required to be connected to the electrical connection pads 121 surrounding the upper package substrate 12, and the first bumps 13 less than 80 microns in size cannot be fabricated by a general printing technique, when the semiconductor chip 11 of the upper package 1 is the semiconductor chip 11 in the form of a fine line width and spacing with more electrode pads (for example, 28 nm or 22 nm process), an area surrounding the upper package substrate 12 should be inevitably increased. Bond wires 14 of the upper package 1 put restrictions on arc height and arc length, resulting in the flexibility of the layout of the electrically connected pads 121 being limited to a wiring range of the bond wires 14 and the thickness of the stacked package being difficult to be reduced. Even if the semiconductor chip 11 of the upper package 1 is electrically bonded in a flip-chip manner, the first bumps 13 are still required to be electrically connected to the lower package 2. Also, the area surrounding the upper package substrate 12 is required to be increased. In a nutshell, the upper package 1 and the lower package 2 are mutually electrically connected by the first bumps 13 and the second bumps 22, resulting in the size of the upper package substrate 12 and the lower package substrate 21 being limited to the size of the diameter of the bumps, and the demand on the present electronic products (i.e. miniaturization, multi-function, high electrical resistance and high-speed operation) cannot be met.

Therefore, it is an important issue to overcome the problem of the prior art.

### SUMMARY OF THE INVENTION

The present invention provides a method of fabricating a stacked package, comprising: providing a first package, having a first encapsulant having a first surface and a second surface opposite to the first surface; a first electrical connection structure formed on the first surface; a plurality of first conductive pillars formed in the first encapsulant, each of the first conductive pillars having two ends connected to the first electrical connection structure and exposed from the second surface, respectively; and a first semiconductor chip disposed in the first encapsulant and electrically connected to the first electrical connection structure; and stacking a second package on the first package, wherein the second package comprises: a second encapsulant having a third surface and a fourth surface opposite to the third surface; a second electrical connection structure formed on the third surface or the fourth surface of the second encapsulant; a second semiconductor chip disposed in the second encapsulant and electrically connected to the second electrical connection structure; and a plurality of second conductive pillars formed in the second encapsulant and electrically connected to the second electrical connection structure; wherein the first electrical conduction pillars are electrically connected to the second conductive pillars.

The present invention further provides a stacked package, including: a first package, comprising: a first encapsulant having a first surface and a second surface opposite to the first surface; a first electrical connection structure formed on the first surface; a plurality of first conductive pillars formed in the first encapsulant, each of the first conductive pillars having two ends connected to the first electrical connection structure and exposed from the second surface, respectively; and a first semiconductor chip disposed in the first encapsulant and electrically connected to the first electrical connection structure; and a second package stacked on the first package, wherein the second package comprises: a second encapsulant having a third surface and a fourth surface opposite to the third surface; a second electrical connection structure formed on the third surface or the fourth surface of the second encapsulant; a second semiconductor chip disposed in the second encapsulant and electrically connected to the second electrical connection structure; and a plurality of second conductive pillars formed in the second encapsulant and electrically connected to the second electrical connection structure; wherein the first electrical conduction pillars are electrically connected to the second conductive pillars.

As can be seen from the foregoing, the present invention uses conductive pillars for electrically connecting the first and second packages. The diameter of the conductive pillars (about 50 microns) is much less than the diameter of the conventional bumps (about 250-300 microns). The present invention reduces the pitches of the electrically connecting points from conventional 300 to 400 microns to about 100 microns. The package fabricated according to the present invention can tolerate more inputs and outputs (I/O), and is benefit to the miniaturization of the overall stacked package.

### BRIEF DESCRIPTION OF DRAWINGS

The invention can be more fully understood by reading the following detailed description of the preferred embodiments, with reference made to the accompanying drawings, wherein:

FIG. 1 is a sectional view illustrating a stacked package according to the prior art.

FIGS. 2A to 2F are sectional views illustrating a method of fabricating a first package of a stacked package of a first embodiment according to present invention.

FIGS. 3A to 3E are sectional views illustrating a method of fabricating a first package of a stacked package of a second embodiment according to present invention.

FIGS. 4A to 4H are sectional views illustrating a method of fabricating first conductive pillars of a first package of a stacked package according to present invention.

FIGS. 5A to 5C are sectional views illustrating a second package of a stacked package of a different embodiment according to present invention.

FIGS. 6A to 6C are sectional views illustrating a stacked package of a different embodiment according to present invention.

FIG. 7 is a sectional view illustrating a stacked package having three packages according to present invention.

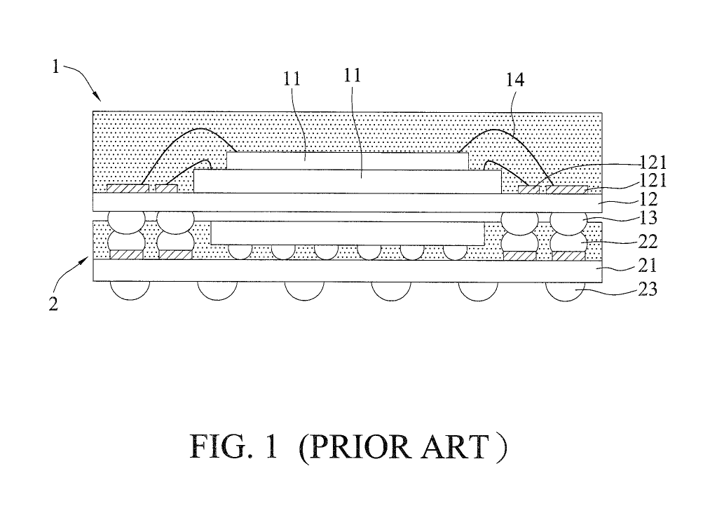

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

These detailed descriptions may include exemplary embodiments in an example manner with respect to structures and/or functions and thus a scope of the present disclosure should not be construed to be limited to such embodiments. In other words, the present disclosure may be embodied in many different forms and should not be construed as limited to the embodiments set forth herein. Rather, these embodiments are provided so that this disclosure will be thorough and complete, and will fully convey the scope of the disclosure to those skilled in the art. The present disclosure is defined only by the categories of the claims, and a scope of the present disclosure may include all equivalents to embody a spirit and idea of the present disclosure.

The terminology used in the present disclosure is for the purpose of describing particular embodiments only and is not intended to limit the disclosure. For example, the terminology used in the present disclosure may be construed as follows.

As used in the disclosure and the appended claims, the singular forms “a”, “an” and “the” are intended to include the plural forms as well, unless context clearly indicates otherwise. It will be further understood that the terms “comprise” and/or “comprising and/or “include” and/or “including” and/or “have” and/or “having”” when used in this specification, specify the presence of stated features, integers, steps, operations, elements, and/or components, but do not preclude the presence or addition of one or more other features, integers, steps, operations, elements, components, and/or groups thereof.

Reference throughout the specification to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

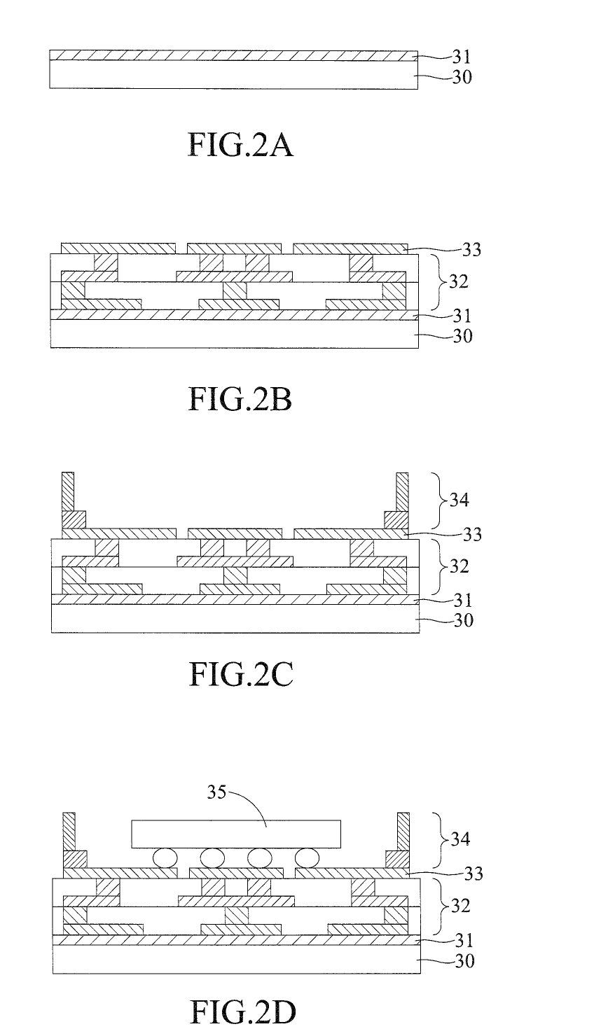

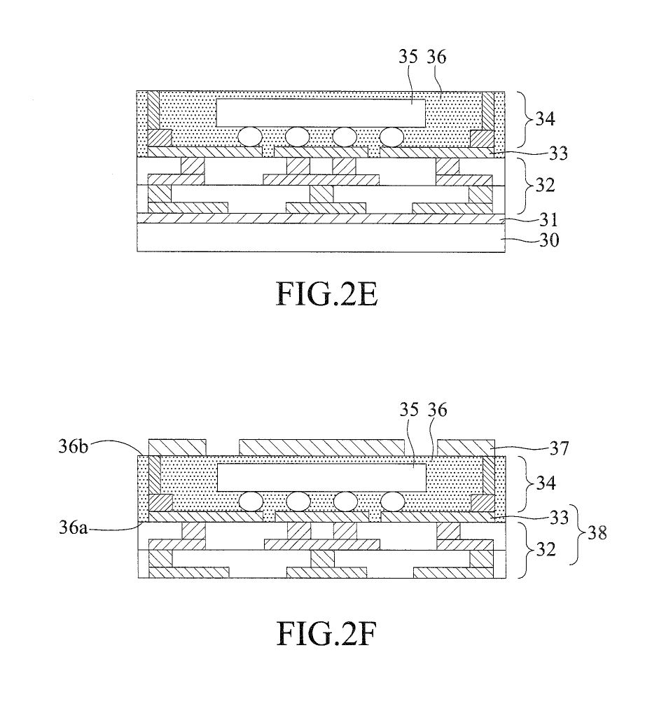

FIGS. 2A to 2F are sectional views illustrating a method of fabricating a first package (lower package) of a stacked package of a first embodiment according to present invention.

As shown in FIG. 2A, a metal layer 31 is formed on a carrier plate 30. In an embodiment, the carrier plate 30 is made of glass, and the metal layer 31 is made of copper.

As shown in FIG. 2B, a first built-up layer 32 is formed on the metal layer 31, and a first circuit layer 33 is formed on the first built-up layer 32.

As shown in FIG. 2C, a plurality of first conductive pillars 34 are formed on the first circuit layer 33.

As shown in FIG. 2D, a first semiconductor chip 35 is disposed on the first circuit layer 33 in a flip-chip manner. In an embodiment, a plurality first semiconductor chips 35 are disposed on the first circuit layer 33, or the first semiconductor chip 35 is a stacked semiconductor chip set.

As shown in FIG. 2E, a first encapsulant 36 for encapsulating the first semiconductor chip 35 and the first conductive pillars 34 is formed on the first build-up layer 32, and one end of each of the first conductive pillars 34 is exposed from the surface of the first encapsulant 36.

As shown in FIG. 2F, a third electrical connection structure 37 electrically connected to the first conductive pillars 34 is formed on the first encapsulant 36. The third electrical connection structure 37 includes a third circuit layer. The carrier plate 30 and the metal layer 31 are removed.

Referring to FIG. 2F, the first package disclosed in the present invention has a first encapsulant 36 having a first surface 36a and a second surface 36b opposite to the first surface 36a; a first electrical connection structure 38 formed on the first surface 36a, the first electrical connection structure 38 including a first circuit layer 33 and a first built-up layer 32 formed on the first circuit layer 33; a plurality of first conductive pillars 34 formed in the first encapsulant 36, each of the first conductive pillars 34 having two ends connected to the first electrical connection structure 38 and exposed from the second surface 36b, respectively; and a first semiconductor chip 35 disposed in the first encapsulant 36 and electrically connected to the first electrical connection structure 38; and a third electrical connection structure 37 formed on the second surface 36b.

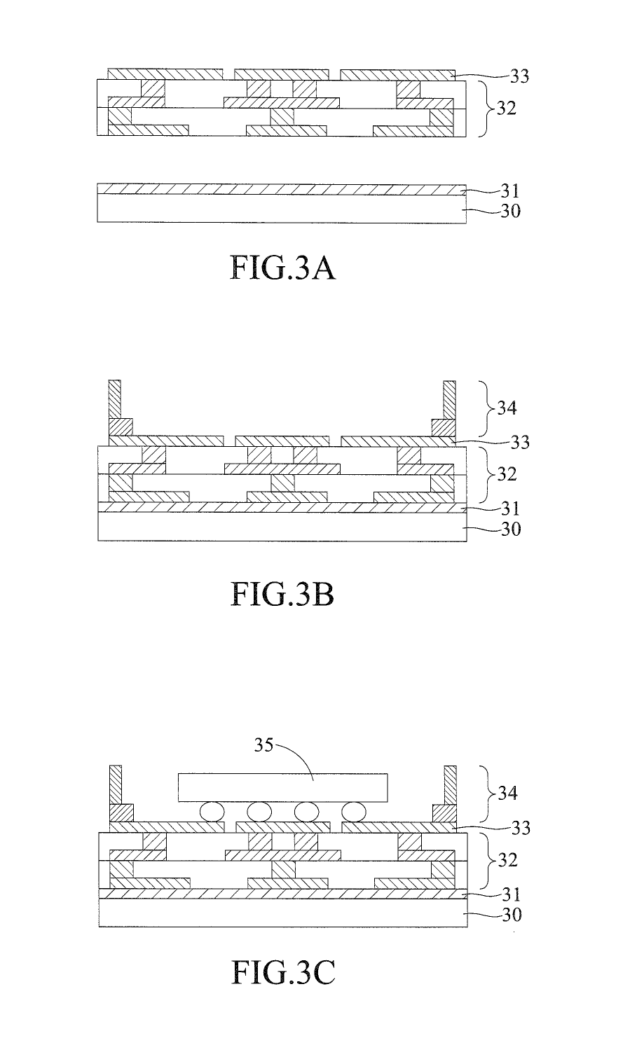

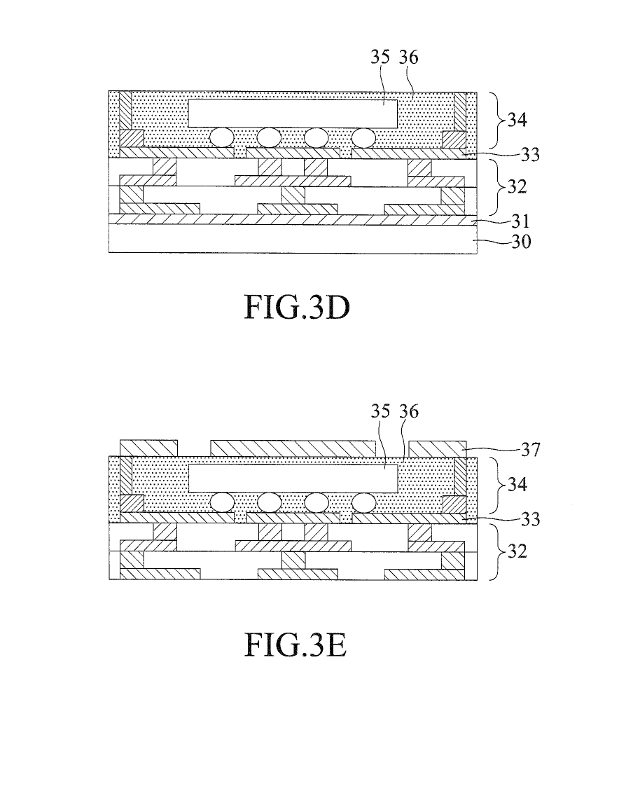

FIGS. 3A to 3E are sectional views illustrating a method of fabricating a first package (lower package) of a stacked package of a second embodiment according to present invention.

As shown in FIG. 3A, a first built-up layer 32 is provided, and the first circuit layer 33 is formed on the first built-up layer 32. Another surface side of the first built-up layer 32 opposite to a surface side of the build-up layer 32 where the first circuit layer 33 is formed, is attached to the metal layer 31 on the carrier plate 30.

The steps shown in FIGS. 3B to 3E are substantially the same as those shown in FIGS. 2C to 2F, further description is hereby omitted.

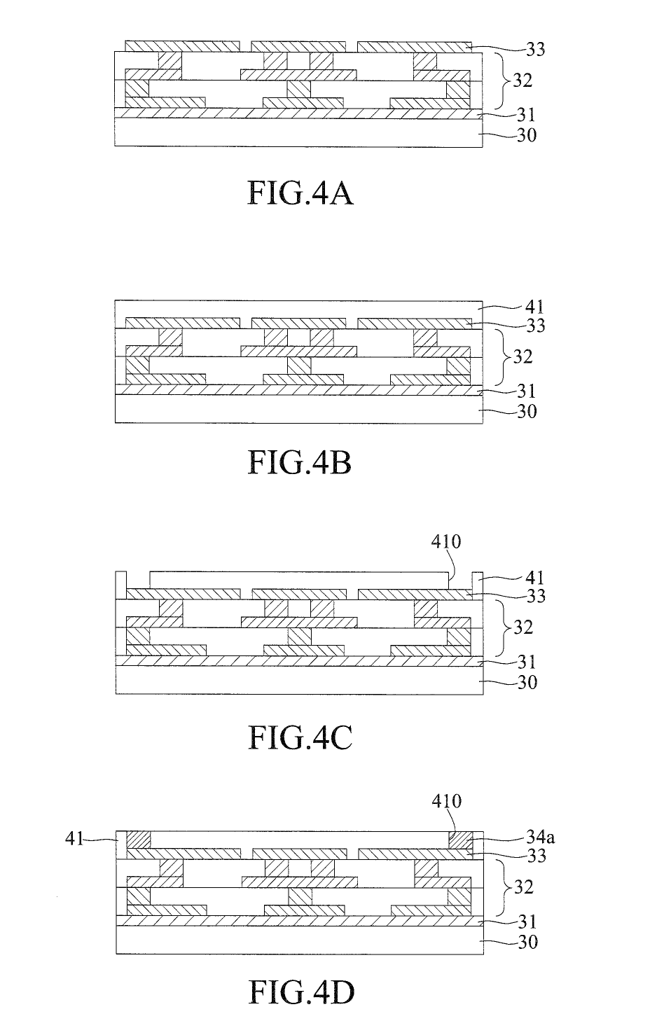

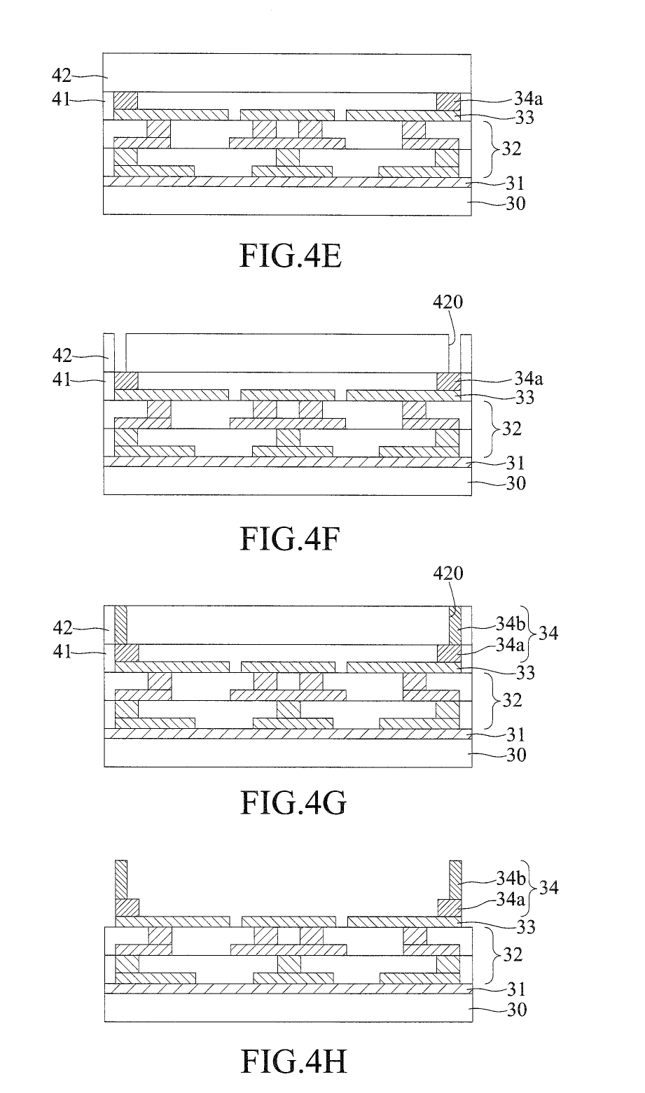

FIGS. 4A to 4H are sectional views illustrating a method of fabricating first conductive pillars of a first package of a stacked package according to present invention.

If the first conductive pillars 34 are shorter than 100 microns, a general plating is used. If the first conductive pillars 34 are taller than 200 microns, it is recommended that the following double plating is used.

As shown in FIG. 4A, a structure as shown in FIG. 2B is provided.

As shown in FIG. 4B, a first dry film 41 is formed on the first build-up layer 32 and the first circuit layer 33.

As shown in FIG. 4C, a plurality of first openings 410 for exposing a portion of the first circuit layer 33 are formed in the first dry film, by for example, photolithographic exposure or development processes.

As shown in FIG. 4D, a first metal part 34a is formed in each of the first openings 410.

As shown in FIG. 4E, a second dry film 42 is formed on the first dry film 41.

As shown in FIG. 4F, a plurality of second openings 420 for exposing a portion of the first metal part 34a are formed in the second dry film 42.

As shown in FIG. 4G, a second metal part 34b connected to the first metal part 34a is formed in each of the second openings 420. The first metal part 34a and the second metal part 34b are formed into the first conductive pillar 34.

As shown in FIG. 4H, the second dry film 42 and the first dry film 41 are removed.

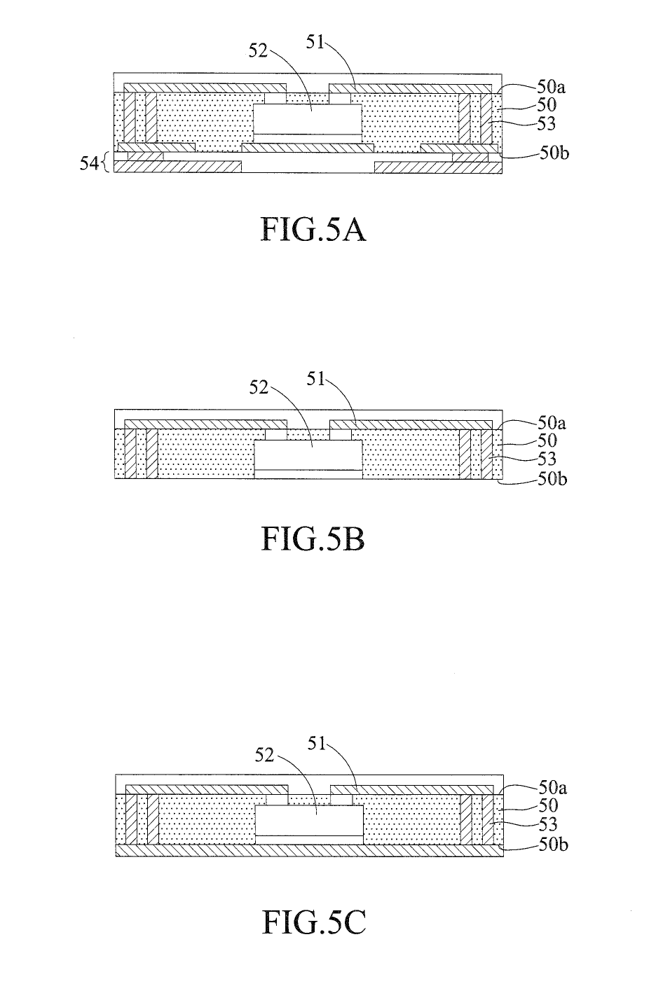

FIGS. 5A to 5C are sectional views illustrating a second package (upper package) of a stacked package of a different embodiment according to present invention. The method is similar to the method of fabricating the first package, which is not described again herein.

As shown in FIGS. 5A to 5C, the second package has a second encapsulant 50 having a third surface 50a and a fourth surface 50b opposite to the third surface 50a; a second electrical connection structure 51 formed on the third surface 50a or the fourth surface 50b of the second encapsulant 50, the second electrical connection structure including a second circuit layer; a second semiconductor chip 52 disposed in the second encapsulant 50 and electrically connected to the second electrical connection structure 51 using a flip-chip technique or a wire bonding technique (alternatively, a plurality of second semiconductor chips 52 are disposed in the second encapsulant 50, or a stacked semiconductor chip set is disposed in the second encapsulant 50); and a plurality of second conductive pillars 53 formed in the second encapsulant 50 and electrically connected to the second electrical connection structure 51.

In an embodiment, the second electrical connection structure 51 is formed on the third surface 50a of the second encapsulant 50, and a second built-up layer 54 is further formed on the fourth surface 50b of the second encapsulant 50.

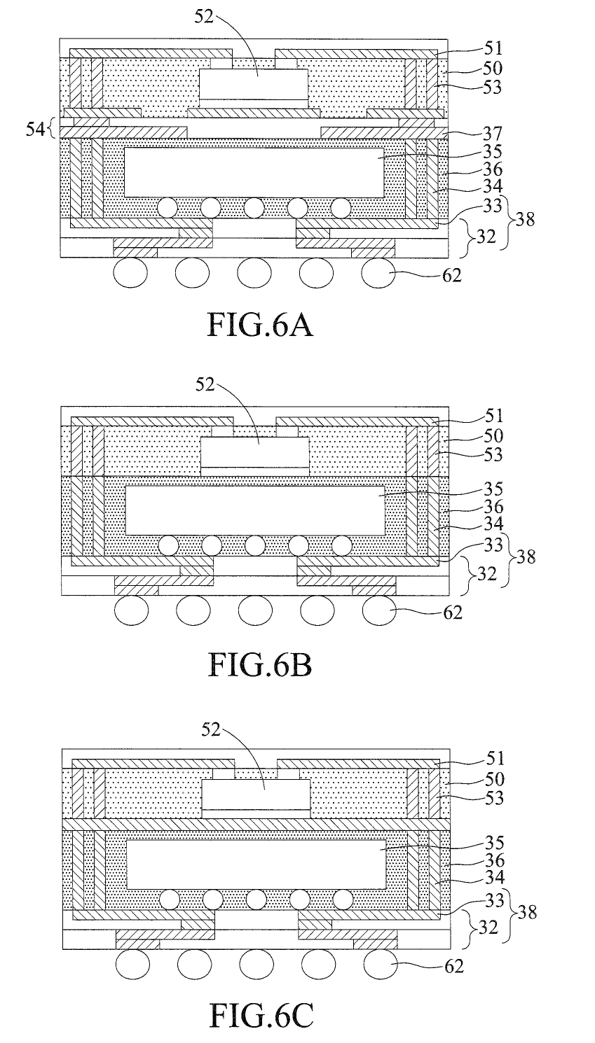

FIGS. 6A to 6C are sectional views illustrating a stacked package of a different embodiment according to present invention.

As shown in FIGS. 6A to 6C, the second package is stacked on the first package, and the first conductive pillars 34 of the first package are electrically connected to the second conductive pillars 53 of the second package.

In an embodiment, the stacked package further includes a solder paste (not shown) formed between the first package and the second package, and the first conductive pillars 34 are electrically connected to the second conductive pillars 53 by the solder paste.

In an embodiment, a plurality of conductive elements 62 such as bumps are further provided on the first build-up layer 32.

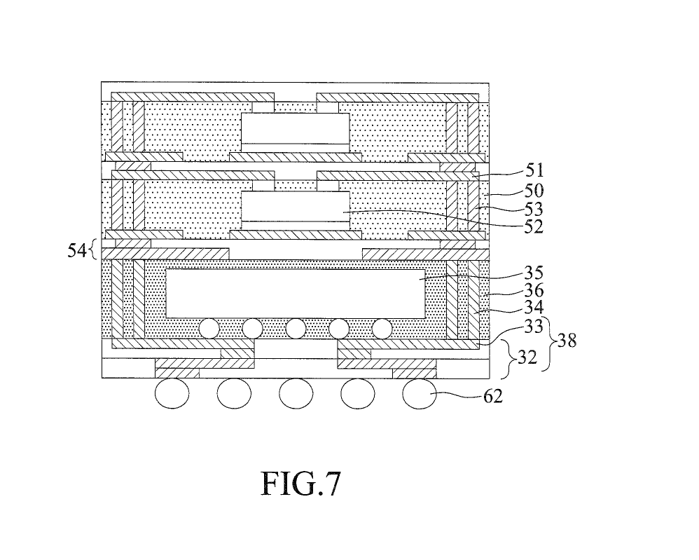

FIG. 7 is a sectional view illustrating a stacked package having three packages according to present invention. One (or more than one) more package (e.g., a third package) may be stacked on the second package.

In summary, since the present invention utilizes conductive pillars for electrically connecting the packages, and the diameter of the conductive pillars (about 50 microns) is much less than the diameter of the conventional bumps (about 250-300 microns), the present invention can reduce the pitches of the electrically connecting points from conventional 300 to 400 microns to about 100 microns, and the package of the present invention can tolerate more inputs and outputs (I/O), and give advantages for the miniaturization of the overall stacked package.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

What is claimed is:

1. A method of fabricating a stacked package, comprising:
providing a first package, wherein the first package comprises:
a first encapsulant having a first surface and a second surface opposite to the first surface;
a first electrical connection structure formed on the first surface;
a plurality of first conductive pillars formed in the first encapsulant, each of the first conductive pillars having two ends connected to the first electrical connection structure and exposed from the second surface of the first encapsulant respectively; and
a first semiconductor chip disposed in the first encapsulant and electrically connected to the first electrical connection structure; and
stacking a second package on the first package, wherein the second package comprises:
a second encapsulant having a third surface and a fourth surface opposite to the third surface;
a second electrical connection structure formed on the third surface or the fourth surface of the second encapsulant;
a second semiconductor chip disposed in the second encapsulant and electrically connected to the second electrical connection structure; and
a plurality of second conductive pillars formed in the second encapsulant and electrically connected to the second electrical connection structure; wherein the first electrical conduction pillars are electrically connected to the second conductive pillars.

2. The method of claim 1, wherein the first electrical connection structure includes a first circuit layer and a first built-up layer formed on the first circuit layer.

3. The method of claim 2, wherein the first package further includes a third electrical connection structure formed on the second surface.

4. The method of claim 3, wherein the third electrical connection structure includes a third circuit layer.

5. The method of claim 3, wherein the first package is formed by:
providing a carrier plate having a metal layer;
forming the first built-up layer on the metal layer;
forming the first circuit layer on the first built-up layer;
forming the first conductive pillars on the first circuit layer;
attaching the first semiconductor chip to the first circuit layer;
forming on the first built-up layer the first encapsulant to encapsulate the first semiconductor chip and the first conductive pillars, with one end of each of the first conductive pillars exposed from a surface of the first encapsulant;
forming on the first encapsulant the third electrical connection structure electrically connected to the first conductive pillars; and
removing the carrier plate and the metal layer.

6. The method of claim 5, wherein the first conductive pillars are formed by:
forming a first dry film on the first built-up layer and the first circuit layer;
forming in the first dry film a plurality of first openings to expose a portion of the first circuit layer to the outside;
forming a first metal part in each of the first openings;
forming a second dry film on the first dry film;
forming in the second dry film a plurality of second openings for exposing the first metal part;
forming in each of the second openings a second metal part connected to the first metal part, such that the first metal part and the second metal part constitute are formed into the first conductive pillar; and
removing the second dry film and the first dry film.

7. The method of claim 3, wherein the first package is formed by:
providing the first built-up layer on which the first circuit layer is formed;
attaching the first built-up layer to a metal layer on a carrier plate via a side of the first built-up layer free from being formed with the first circuit layer;
forming the first conductive pillars on the first circuit layer;
attaching the first semiconductor chip to the first circuit layer;
forming on the first built-up layer the first encapsulant for encapsulating the first semiconductor chip and the first conductive pillars with one end of each of the first conductive pillars exposed from the first encapsulant;
forming on the first encapsulant the third electrical connection structure electrically connected to the first conductive pillars; and
removing the carrier plate and the metal layer.

8. The method of claim 7, wherein the first conductive pillars are formed by:
forming a first dry film on the first built-up layer and the first circuit layer;
forming in the first dry film a plurality of first openings for exposing a portion of the first circuit layer;
forming a first metal part in each of the first openings;
forming a second dry film on the first dry film;
forming in the second dry film a plurality of second openings for exposing the first metal part;
forming in each of the second openings a second metal part connected to the first metal part, wherein the first metal part and the second metal part are formed into the first conductive pillar; and
removing the second dry film and the first dry film.

9. The method of claim 1, wherein the second electrical connection structure includes a second circuit layer.

10. The method of claim 1, further comprising stacking a third package on the second package.

11. The method of claim 1, wherein the first conductive pillars are electrically connected to the second conductive pillars by a solder paste formed between the first package and the second package.

12. The method of claim 1, wherein the second electrical connection structure is formed on the third surface of the second encapsulant, the second package further comprises a second built-up layer formed on the fourth surface of the second encapsulant, and the second package is connected to the first package by the second built-up layer.

13. A stacked package, comprising:
a first package, comprising:
a first encapsulant having a first surface and a second surface opposite to the first surface;
a first electrical connection structure formed on the first surface;
a plurality of first conductive pillars formed in the first encapsulant, and each of the first conductive pillars having two ends connected to the first electrical connection structure and exposed from the second surface respectively; and
a first semiconductor chip disposed in the first encapsulant and electrically connected to the first electrical connection structure; and
a second package stacked on the first package, the second package comprising:
a second encapsulant having a third surface and a fourth surface opposite to the third surface;
a second electrical connection structure formed on the third surface or the fourth surface of the second encapsulant;
a second semiconductor chip disposed in the second encapsulant and electrically connected to the second electrical connection structure; and
a plurality of second conductive pillars formed in the second encapsulant and electrically connected to the second electrical connection structure;
wherein the first electrical conduction pillars are electrically connected to the second conductive pillars.

14. The stacked package of claim 13, wherein the first electrical connection structure includes a first circuit layer and a first built-up layer formed on the first circuit layer.

15. The stacked package of claim 13, wherein the second electrical connection structure includes a second circuit layer.

16. The stacked package of claim 15, wherein the second circuit layer is formed on the third surface of the second encapsulant, the second package further includes a second built-up layer formed on the fourth surface of the second encapsulant, and the second package is electrically connected to the first package by the second built-up layer.

17. The stacked package of claim 13, further comprising a third package stacked on the second package.

18. The stacked package of claim 13, wherein the first package further includes a third electrical connection structure formed on the second surface.

19. The stacked package of claim 13, further comprising a solder paste formed between the first and the second packages, for electrically connecting the first conductive pillars to the second conductive pillars.

20. The stacked package of claim 13, wherein the first conductive pillars are formed by the first metal part and the second metal part.
